(19) United States
(12) Patent Application Publication
(10) Pub. No.: US 2024/0363599 A1
(43) Pub. Date: Oct. 31, 2024

(54) DISPLAY SUBSTRATE AND PREPARATION METHOD THEREFOR, AND DISPLAY APPARATUS

(71) Applicant: BOE Technology Group Co., Ltd., Beijing (CN)

(72) Inventors: Can WANG, Beijing (CN); Qi QI, Beijing (CN); Wei LI, Beijing (CN); Can ZHANG, Beijing (CN); Minghua XUAN, Beijing (CN); Jinfei NIU, Beijing (CN); Jingjing ZHANG, Beijing (CN)

(21) Appl. No.: 18/681,521

(22) PCT Filed: Aug. 17, 2022
(86) PCT No.: PCT/CN2022/113036

§ 371 Date: Feb. 6, 2024

(30) Foreign Application Priority Data
Aug. 26, 2021 (CN) 202110990952.2

(51) Int. Cl. H01L 25/075; H01L 21/683; H01L 33/00; H01L 33/06; H01L 33/42; H01L 33/44; H01L 33/50; H01L 33/52; H01L 33/58; H01L 33/62

(52) U.S. Cl. CPC H01L 25/0753; H01L 21/6835; H01L 33/0093; H01L 33/06; H01L 33/42; H01L 33/44; H01L 33/50; H01L 33/52; H01L 33/58; H01L 33/62; H01L 2221/68354; H01L 2221/68363; H01L 2221/68386; H01L 2933/0041; H01L 2933/005; H01L 2933/0058; H01L 2933/0066; H01L 2933/0091

(57) ABSTRACT

A method for preparing the display substrate includes: providing a first substrate, and forming a light emitting chip layer on the first substrate to form a first backplane, wherein the light emitting chip layer includes: light emitting chips arranged in array, which are configured to emit light of a first color and include N sub-pixels, and N is a positive integer greater than or equal to 1; providing a second substrate, and forming a drive circuit layer on the second substrate to form a second backplane, wherein the drive circuit layer includes: connection electrodes arranged in an array, and the light emitting chips correspond to the connection electrodes one-by-one; transferring the first backplane from which the first substrate is peeled off to the second backplane; forming an optical film layer on a side of the light emitting chip layer away from the second backplane.

### CROSS-REFERENCE TO RELATED APPLICATIONS

The present application is a U.S. National Phase Entry of International Application PCT/CN2022/113036 having an international filing date of Aug. 17, 2022, which claims priority of Chinese Patent Application No. 202110990952.2 filed to the CNIPA on Aug. 26, 2021 and entitled “Display Substrate and Preparation Method Therefor, and Display Apparatus”, the contents of which are hereby incorporated herein by reference in their entireties.

### Technical Field

Embodiments of the present disclosure relate to, but are not limited to, the field of display technologies, and particularly, to a display substrate and a method for preparing the display substrate, and a display apparatus.

### BACKGROUND

A semiconductor Light Emitting Diode (LED) technology has been developed for nearly 30 years, from an initial solid-state lighting power supply to a backlight in the display field, and then to an LED display screen, providing a solid foundation for its wider applications. Herein, with development of chip fabrication and an encapsulation technology, a backlight using sub-millimeter-scale or even micron-scale Micro LEDs has been widely used.

### SUMMARY

The following is a summary of the subject matter described in the present disclosure in detail. The summary is not intended to limit the scope of protection of the claims.

In a first aspect, the present disclosure further provides a method for preparing a display substrate, and the method includes:
providing a first substrate, and forming a light emitting chip layer on the first substrate to form a first backplane, wherein the light emitting chip layer includes light emitting chips arranged in an array, which are configured to emit light of a first color and comprise N sub-pixels, and N is a positive integer greater than or equal to 1;
providing a second substrate, and forming a drive circuit layer on the second substrate to form a second backplane, wherein the drive circuit layer includes connection electrodes arranged in an array, and the light emitting chips are in one-to-one correspondence with the connection electrodes;
transferring the first backplane from which the first substrate is peeled off to the second backplane to make the light emitting chips be electrically connected with corresponding connection electrodes; and
forming an optical film layer on a side of the light emitting chip layer away from the second backplane, wherein the optical film layer is configured to scatter the light of the first color, convert the light of the first color into light of a second color, and convert the light of the first color into light of a third color.

In some possible implementations, each sub-pixel includes a first pixel semiconductor layer, a second pixel semiconductor layer, a pixel multiple quantum well layer, a first electrode and a second electrode;
forming the light emitting chip layer on the first substrate includes:
sequentially growing a buffer layer, a first semiconductor layer, a multiple quantum well layer, a second semiconductor layer, a transparent conductive layer, a first insulation layer and a pad layer on a side of the first substrate, wherein the first semiconductor layer includes a first pixel semiconductor layer, the multiple quantum well layer includes a pixel multiple quantum well layer, the second semiconductor layer includes a second pixel semiconductor layer, the transparent conductive layer includes the first electrode, and the pad layer includes the second electrode and a pad which is connected with the first electrode;
when N is greater than 1, first pixel semiconductor layers of different sub-pixels are a same film layer, pixel multiple quantum well layers, second pixel semiconductor layers and first electrodes of different sub-pixels are spaced apart from each other, second electrodes of different sub-pixels are a same electrode, and the first electrodes of different sub-pixels are connected with different pads; and
an orthographic projection of the pad on the first substrate is at least partially overlapped with or not overlapped with an orthographic projection of the first electrode to which the pad is connected on the first substrate.

In some possible implementations, forming the drive circuit layer on the second substrate includes:
sequentially forming a drive structure layer, a first planarization layer, a metal conductive layer, a second insulation layer, a second planarization layer and a solder paste layer on the second substrate, wherein the metal conductive layer includes a connection electrode, and the solder paste layer includes solder paste structures arranged in an array;
when N=1, each connection electrode includes a first sub-connection electrode and a second sub-connection electrode, wherein the first sub-connection electrode is electrically connected to a first electrode in a corresponding light emitting chip, and the second sub-connection electrode is electrically connected to a second electrode in a corresponding light emitting chip;
when N is not equal to 1, each connection electrode includes N first sub-connection electrodes and one second sub-connection electrode, wherein the N first sub-connection electrodes are respectively electrically connected with first electrodes of N sub-pixels in a corresponding light emitting chip, and the second sub-connection electrode is electrically connected with second electrodes of N sub-pixels in the corresponding light emitting chip; and each of the sub-connection electrodes is connected to one solder paste structure, and different sub-connection electrodes are connected to different solder paste structures.

In some possible implementations, transferring the first backplane from which the first substrate is peeled off to the second backplane includes:
transferring the first backplane to the second backplane to make the light emitting chips be electrically connected with the corresponding connection electrodes; and
peeling off the first substrate through a laser peeling process.

In some possible implementations, transferring the first backplane from which the first substrate is peeled off to the second backplane includes:
transferring the first backplane to a third backplane to make the third backplane be bonded with the light emitting chip layer;
peeling off the first substrate through a laser peeling process; and
peeling off the third backplane, and transferring the light emitting chip layer bonded with the third backplane to the second backplane.

In some possible implementations, forming the optical film layer on the side of the light emitting chip layer away from the second backplane includes:
forming a colloid layer through a coating or glue dispensing process on the side of the light emitting chip layer away from the second backplane;
forming a black matrix layer on the colloid layer, wherein the black matrix layer is provided with a first via hole exposing each sub-pixel in the light emitting chip;
sequentially forming a retaining wall and an optical film layer on the black matrix layer, wherein the optical film layer includes a first optical sub-film layer, a second optical sub-film layer and a third optical sub-film layer; the first optical sub-film layer is configured to convert the light of the first color into the light of the second color, the second optical sub-film layer is configured to convert the light of the first color into the light of the third color, and the third optical sub-film layer is configured to scatter the light of the first color;
when N=1, each sub-pixel includes one of the first optical sub-film layer, the second optical sub-film layer, and the third optical sub-film layer; sub-pixels of adjacent light emitting chips include different optical sub-film layers;
when N=3, three sub-pixels located in a same light emitting chip respectively include the first optical sub-film layer, the second optical sub-film layer and the third optical sub-film layer, three sub-pixels located in different light emitting chips include a same optical sub-film layer, or the three sub-pixels located in the same light emitting chip include the same optical sub-film layer, and the three sub-pixels located in different light emitting chips include different optical sub-film layers;
when N is a positive integer that is not equal to 1 and not equal to 3, the three sub-pixels located in the same light emitting chip include a same optical sub-film layer, and the three sub-pixels located in different light emitting chips include different optical sub-film layers; and
an orthographic projection of the optical sub-film layer in each sub-pixel on the second backplane is overlapped at least partially with an orthographic projection of the multiple quantum well layer in each sub-pixel on the second backplane.

In some possible implementations, sequential forming the retaining wall and the optical film layer on the black matrix layer includes:
forming the retaining wall on the black matrix layer, wherein the retaining wall is provided with a second via hole exposing the first via hole; and
depositing a first optical thin film, a second optical thin film and a third optical thin film on the retaining wall, processing the first optical thin film through a patterning process to form the first optical sub-film layer, processing the second optical thin film through a patterning process to form the second optical sub-film layer, and processing the third optical thin film through a patterning process to form the third optical sub-film layer.

In some possible implementations, sequentially forming the retaining wall and the optical film layer on the black matrix layer includes:
forming the retaining wall on the black matrix layer, wherein an orthographic projection of the retaining wall on the second backplane covers an orthographic projection of the first via hole on the second backplane; and
injecting first optical particles, second optical particles and third optical particles into the retaining wall to form the first optical sub-film layer, the second optical sub-film layer and the third optical sub-film layer.

In some possible implementations, after forming the optical film layer on the side of the light emitting chip layer away from the second backplane, the method further includes:
sequentially forming an organic encapsulation layer and a first inorganic encapsulation layer on the optical film layer.

In some possible implementations, after forming the optical film layer on a side of the light emitting chip layer away from the second backplane, the method further includes:
forming a second inorganic encapsulation layer on the optical film layer;
forming a color film layer on the second inorganic encapsulation layer, wherein the color film layer includes a first color film layer, a second color film layer and a third color film layer; the first color film layer is in one-to-one correspondence with the first optical sub-film layer, an orthographic projection of the first color film layer on the second backplane covers an orthographic projection of the corresponding first optical sub-film layer on the second backplane, the second color film layer is in one-to-one correspondence with the second optical sub-film layer, an orthographic projection of the second color film layer on the second backplane covers an orthographic projection of the corresponding second optical sub-film layer on the second backplane, the third color film layer is in one-to-one correspondence with the third optical sub-film layer, and an orthographic projection of the third color film layer on the second backplane covers an orthographic projection of the corresponding third optical sub-film layer on the second backplane; and
sequentially forming an organic encapsulation layer and a first inorganic encapsulation layer on the color film layer.

In some possible implementations, the first substrate is a sapphire substrate.

In a second aspect, the present disclosure further provides a display substrate, which is prepared by using the method for preparing the display substrate.

In a third aspect, the present disclosure further provides a display apparatus including the display substrate described above.

After the drawings and the detailed descriptions are read and understood, other aspects may be comprehended.

### BRIEF DESCRIPTION OF DRAWINGS

The accompany drawings are used to provide further understanding of the technical solution of the present disclosure, and form a part of the description. The accompany drawings and embodiments of the present disclosure are used to explain the technical solution of the present disclosure, and do not form limitations on the technical solution of the present disclosure.

FIG. 1 is a flowchart of a method for preparing a display substrate according to an embodiment of the present disclosure.

FIG. 2A is a cross-sectional view of a first backplane according to an exemplary embodiment.

FIG. 2B is a cross-sectional view of a first backplane according to another exemplary embodiment.

FIG. 2C is a cross-sectional view of a first backplane according to another exemplary embodiment.

FIG. 2D is a cross-sectional view of a first backplane according to another exemplary embodiment.

FIG. 2E is a schematic view of an arrangement of sub-pixels in an exemplary embodiment.

FIG. 2F is a top view of a pad layer in an exemplary embodiment.

FIG. 3A is a schematic view after a buffer layer is formed.

FIG. 3B is a schematic view after a first semiconductor layer is formed.

FIG. 3C is a schematic view after a multiple quantum well layer is formed.

FIG. 3D is a schematic view after a second semiconductor layer is formed.

FIG. 3E is a schematic view after a transparent conductive layer is formed.

FIG. 3F is a schematic view after an insulation layer is formed.

FIG. 4A is a schematic view of a second backplane according to an exemplary embodiment.

FIG. 4B is a schematic view of a second backplane according to another exemplary embodiment.

FIG. 5A is a schematic view after a drive structure layer is formed.

FIG. 5B is a schematic view after a first planarization layer is formed.

FIG. 5C is a schematic view after a metal conductive layer is formed.

FIG. 5D is a schematic view after a second insulation layer is formed.

FIG. 5E is a schematic view after a second planarization layer is formed.

FIG. 6A to FIG. 6B are schematic views of step S3 according to an exemplary embodiment.

FIG. 7A to FIG. 7B are schematic views of step S3 according to another exemplary embodiment.

FIG. 8A is a schematic view of forming a colloid layer.

FIG. 8B is a schematic view after a black matrix layer is formed.

FIG. 8C is a first schematic view after a retaining wall is formed.

FIG. 8D is a second schematic view after a retaining wall is formed.

FIG. 8E is a first schematic view after an optical film layer is formed.

FIG. 8F is a second schematic view after an optical film layer is formed.

FIG. 9A is a first schematic view after a first inorganic encapsulation layer is formed according to an exemplary embodiment.

FIG. 9B is a second schematic view after a first inorganic encapsulation layer is formed according to an exemplary embodiment.

FIG. 9C is a third schematic view after a first inorganic encapsulation layer is formed according to an exemplary embodiment.

FIG. 9D is a fourth schematic view after a first inorganic encapsulation layer is formed according to an exemplary embodiment.

FIG. 9E is a fifth schematic view after a first inorganic encapsulation layer is formed according to an exemplary embodiment.

FIG. 9F is a sixth schematic view after a first inorganic encapsulation layer is formed according to an exemplary embodiment.

FIG. 10A is a first schematic view after a first inorganic encapsulation layer is formed according to another exemplary embodiment.

FIG. 10B is a second schematic view after a first inorganic encapsulation layer is formed according to another exemplary embodiment.

FIG. 10C is a third schematic view after a first inorganic encapsulation layer is formed according to another exemplary embodiment.

FIG. 10D is a fourth schematic view after a first inorganic encapsulation layer is formed according to another exemplary embodiment.

FIG. 10E is a fifth schematic view after a first inorganic encapsulation layer is formed according to another exemplary embodiment.

FIG. 10F is a sixth first schematic view after a first inorganic encapsulation layer is formed according to another exemplary embodiment.

### DETAILED DESCRIPTION

To make the objectives, technical solutions, and advantages of the present disclosure clearer, the embodiments of the present disclosure will be described in detail below with reference to the accompany drawings. It is to be noted that the implementations may be practiced in various forms. Those of ordinary skills in the art can easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict. In order to keep following description of the embodiments of the present disclosure clear and concise, detailed description of part of known functions and known components are omitted in the present disclosure. The drawings in the embodiments of the present disclosure relate only to the structures involved in the embodiments of the present disclosure, and other structures may be described with reference to conventional designs.

In the accompanying drawings, a size of each composition element, a thickness of a layer, or a region may be exaggerated sometimes for clarity. Therefore, an implementation of the present disclosure is not always limited to the size, and the shape and size of each component in the drawings do not reflect an actual scale. In addition, the accompanying drawings schematically illustrate ideal examples, and an implementation of the present disclosure is not limited to the shapes, numerical values, or the like shown in the drawings.

Ordinal numerals “first”, “second”, “third”, etc., in the specification are set not to form limits in number but only to avoid confusion between composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the composition elements may be changed as appropriate based on a direction according to which each composition element is described. Therefore, appropriate replacements based on situations are allowed, not limited to the expressions in the specification.

In the specification, unless otherwise specified and defined, terms “mounting”, “mutual connection”, and “connection” should be generally understood. For example, a connection may be fixed connection, or detachable connection, or integral connection. It may be mechanical connection or electrical connection. It may be direct connection, or indirect connection through an intermediate, or communication inside two elements. Those of ordinary skills in the art can understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source region. It is to be noted that in the specification, the channel region refers to a region through which a current mainly flows.

In the specification, a first electrode may be a drain electrode, and a second electrode may be a source electrode. Alternatively, the first electrode may be a source electrode, and the second electrode may be a drain electrode. In cases that transistors with opposite polarities are used, or a current direction changes during operation of a circuit, or the like, functions of the “source electrode” and the “drain electrode” may sometimes be exchanged. Therefore, the “source electrode” and the “drain electrode” may be exchanged in the specification.

In the specification, “electrical connection” includes connection of the composition elements through an element with a certain electrical action. “An element with a certain electric action” is not particularly limited as long as electric signals between the connected composition elements may be sent and received. Examples of the “element with the certain electrical action” not only include electrodes and wirings, but also include switch elements such as transistors, resistors, inductors, capacitors, other elements with various functions, etc.

In the specification, a “film” and a “layer” are interchangeable. For example, a “conductive layer” may be replaced with a “conductive film” sometimes. Similarly, an “insulation film” may be replaced with an “insulation layer” sometimes.

In the present disclosure, “about” refers to that a boundary is not defined so strictly and numerical values within process and measurement error ranges are allowed.

Micro LEDs may include miniature Light Emitting Diodes (Micro Light Emitting Diode, Micro-LED) and sub-millimeter Light Emitting Diodes (Mini Light Emitting Diodes, Mini-LED), which have advantages of small size and high brightness, such that may be widely used in backlight modules of display apparatus. Contrast of a picture of a display product using a Micro LED backlight may reach a level of an Organic Light Emitting Diode (OLED for short) display product, improving a display effect of the picture and providing users with a better visual experience. Furthermore, Micro LED display has gradually become a hot spot of a display panel, and is mainly used in Augmented Reality/Virtual Reality (AR/VR), Television (TV), outdoor display, and other fields.

At present, for Micro LEDs, LED chips are usually miniaturized, arrayed, and thin-filmed by using a miniaturization process technology, and LED chips are transferred to a drive backplane in batches through a mass transfer technology. A typical size (e.g., length) of a Micro-LED may be less than 100 μm, e.g., 10 μm to 50 μm. A typical size (e.g., length) of a Mini-LED may be about 100 μm to 300 μm, e.g., 120 um to 260 μm.

A Micro LED display substrate includes a sapphire substrate, and light emitting chips which are disposed in an array and arranged on the sapphire substrate. Due to existence of the sapphire on the light emitting chips, distances between different light emitting chips are larger, which reduces a resolution and a display effect of the Micro LED display substrate.

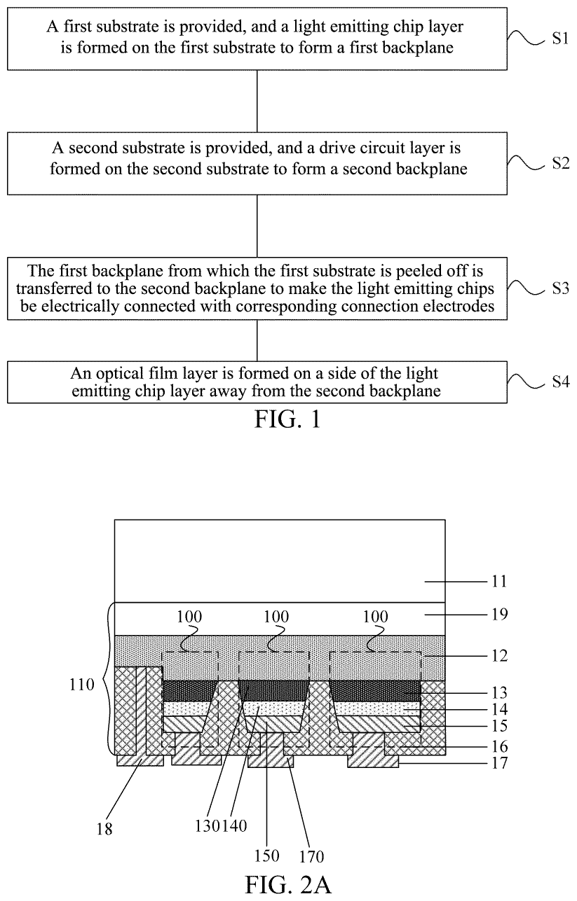

FIG. 1 is a flowchart of a method for preparing a display substrate according to an embodiment of the present disclosure. As shown in FIG. 1, the method for preparing the display substrate according to the embodiment of the present disclosure may include following steps.

In step S1, a first substrate is provided, and a light emitting chip layer is formed on the first substrate to form a first backplane.

In an exemplary embodiment, the light emitting chip layer includes light emitting chips arranged in an array, which are configured to emit light of a first color, and include N sub-pixels, wherein N is a positive integer greater than or equal to 1.

In an exemplary embodiment, the light emitting chips may be Micro LEDs or Mini LEDs.

In an exemplary embodiment, the first color may be blue or may be red or green, which is not limited in the present disclosure.

In an exemplary embodiment, when the light emitting chip includes at least one sub-pixel, the at least one sub-pixel may be arranged in an array, and in this case, the light emitting chip is present in a form of a pixel island.

In an exemplary embodiment, the first substrate may include one of a sapphire substrate, a silicon carbide substrate, a silicon substrate, or a gallium nitride substrate. When the first substrate is a sapphire substrate, a thickness of the first substrate may be about from 55 microns to 65 microns, and exemplarily, the thickness of the first substrate is 60 microns.

In step S2, a second substrate is provided, and a drive circuit layer is formed on the second substrate to form a second backplane.

In an exemplary embodiment, the drive circuit layer includes connection electrodes arranged in an array, and the light emitting chips are in one-to-one correspondence with the connection electrodes.

In an exemplary embodiment, the drive circuit layer may be configured to drive the light emitting chips to emit light, and the second backplane is a drive backplane.

In step S3, the first backplane from which the first substrate is peeled off is transferred to the second backplane to make the light emitting chips be electrically connected with corresponding connection electrodes.

In an exemplary embodiment, the first backplane from which the first substrate is peeled off includes a light emitting chip layer.

In step S4, an optical film layer is formed on a side of the light emitting chip layer away from the second backplane.

In an exemplary embodiment, the optical film layer may be configured to scatter light of a first color, convert the light of the first color to light of a second color, and convert the light of the first color to light of a third color.

In the present disclosure, the display substrate can present various colors through the arrangement of the optical film layer, improving the display effect of the display substrate.

In the present disclosure, at least two sub-pixels are realized in one light emitting chip, which is beneficial for achieving a high PPI design, may reduce dimension pressure of die bonding for multiple times, may reduce binding times and improve a product yield.

A method for preparing the display substrate according to an embodiment of the present disclosure includes: providing a first substrate, and forming a light emitting chip layer on the first substrate to form a first backplane, wherein the light emitting chip layer includes: light emitting chips arranged in an array, which are configured to emit light of a first color and include N sub-pixels, and N is a positive integer greater than or equal to 1; providing a second substrate, and forming a drive circuit layer on the second substrate to form a second backplane, wherein the drive circuit layer includes: connection electrodes arranged in an array, and the light emitting chips correspond to the connection electrodes one-by-one; transferring the first backplane from which the first substrate is peeled off to the second backplane to make the light emitting chips be electrically connected with the corresponding connection electrodes; forming an optical film layer on a side of the light emitting chip layer away from the second backplane, wherein the optical film layer is configured to scatter the light of the first color, convert the light of the first color into light of a second color, and convert the light of the first color into light of a third color. In the present disclosure, distances between the light emitting chips can be reduced and the resolution and display effect of the display substrate can be improved by transferring the first backplane from which the first substrate is peeled off to the second backplane and forming an optical film layer on a side of the first backplane in which the first substrate is peeled off away from the second backplane.

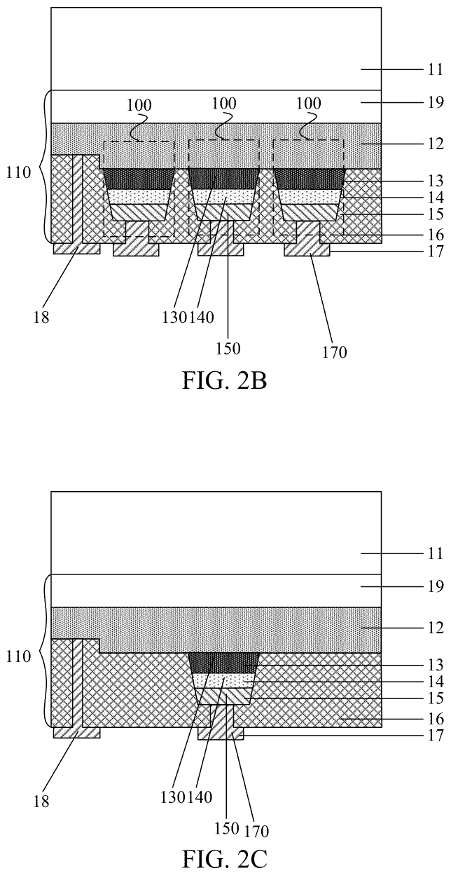

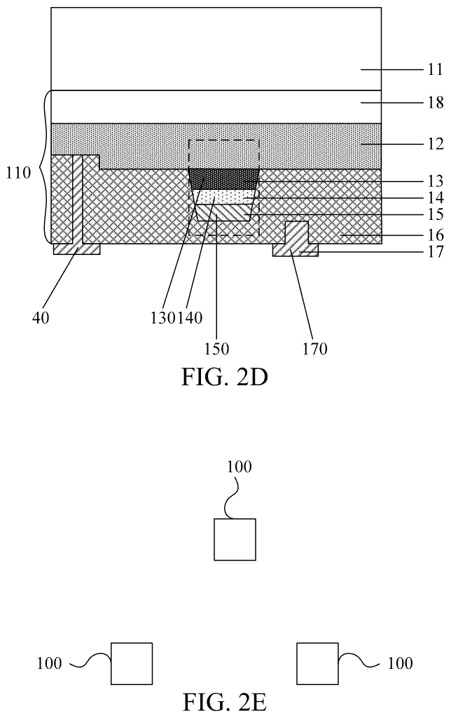

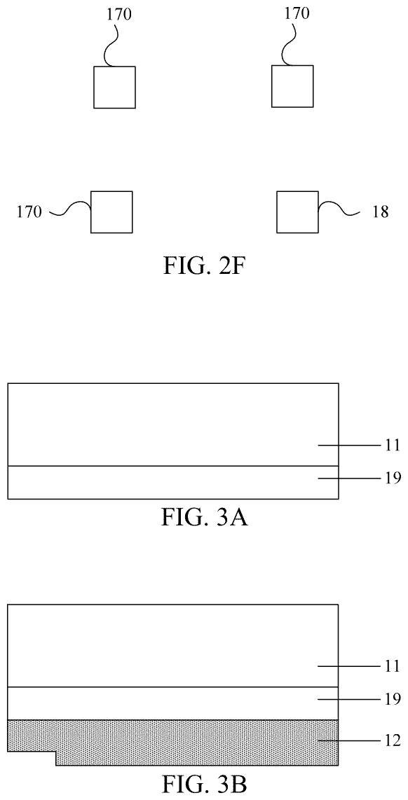

In one exemplary embodiment, FIG. 2A is a cross-sectional view of a first backplane according to an exemplary embodiment, FIG. 2B is a cross-sectional view of a first backplane according to another exemplary embodiment, FIG. 2C is a cross-sectional view of a first backplane according to another exemplary embodiment, and FIG. 2D is a cross-sectional view of a first backplane according to another exemplary embodiment. As shown in FIG. 2A to FIG. 2D, each light emitting chip includes: at least one sub-pixel 100, and each sub-pixel includes a first pixel semiconductor layer 12, a second pixel semiconductor layer 140, a pixel multiple quantum well layer 130, a first electrode 150, and a second electrode 18. FIG. 2A and FIG. 2B are illustrated by taking each light emitting chip including three sub-pixels as an example. FIG. 2C is illustrated by taking each light emitting chip including one sub-pixel as an example.

FIG. 2E is a schematic view of an arrangement of sub-pixels in an exemplary embodiment. As shown in FIG. 2E, when the number of sub-pixels is plural, the sub-pixels may be arranged side by side horizontally, side by side vertically, in a delta-shaped form or in a manner of a positive direction, which is not limited in the present disclosure. FIG. 2 is illustrated by taking that three sub-pixels being arranged in a delta-shaped form as an example.

In an exemplary embodiment, when the light emitting chip includes at least two sub-pixels, sizes of different sub-pixels located in the same light emitting chip may be different or may be the same. Different sub-pixels located in the same light emitting chip in FIG. 2A have different sizes and sub-pixels located in the same light emitting chip in FIG. 2B have the same sizes.

In an exemplary embodiment, Step S1 may include sequentially growing a buffer layer 19, a first semiconductor layer 12, a multiple quantum well layer 13, a second semiconductor layer 14, a transparent conductive layer 15, a first insulation layer 16, and a pad layer 17 on a side of the first substrate. The multiple quantum well layer 13 includes a pixel multiple quantum well layer 130, the second semiconductor layer 14 includes a second pixel semiconductor layer 140, the transparent conductive layer 15 includes a first electrode 150, and the pad layer 17 includes a second electrode 18 and a pad 170, and the pad 170 is connected to the first electrode 150.

As shown in FIG. 2A and FIG. 2B, when N is greater than 1, the first semiconductor layers of different sub-pixels are a same film layer, the multiple quantum well layers, the second semiconductor layers and the first electrode of different sub-pixels are arranged are spaced apart from each other, the second electrodes of different sub-pixels are a same electrode, and the first electrodes of different sub-pixels are connected with different pads.

In an exemplary embodiment, an orthographic projection of the pad 170 on the first substrate 11 may be at least partially overlapped with or not be overlapped with an orthographic projection of the first electrode 150 to which the pad 170 is connected on the first substrate. FIG. 2A to FIG. 2C are illustrated by taking that the orthographic projection of the pad 170 on the first substrate 11 may at least partially overlapped with the orthographic projection of the first electrode 150 to which the pad 170 is connected on the first substrate as an example. FIG. 2D is illustrated by taking that the orthographic projection of the pad 170 on the first substrate 11 is not partially overlapped with the orthographic projection of the first electrode 150 to which the pad 170 is connected on the first substrate as an example. Herein, FIG. 2D is illustrated by taking that the light emitting chip includes one sub-pixel as an example, and the light emitting chip may also include a plurality of sub-pixels, which is not taken as an example in the present disclosure. A positional relationship between the pad and the first electrode in the present disclosure may make the arrangement of the display substrate more flexible.

FIG. 2F is a top view of a pad layer in an exemplary embodiment. As shown in FIG. 2F, when the number of sub-pixels is three, a distribution of the pads 170 and the second electrodes 18 may be a square or another shape, which is not limited here in this disclosure. FIG. 2F is illustrated by taking that the pads 170 and the second electrodes 18 being distributed in a square as example.

In an exemplary embodiment, when the orthographic projection of the pad 170 on the first substrate 11 is not overlapped with an orthographic projection of the first electrode 150 to which the pad 170 is connected on the first substrate, step S1 may further include forming a connection line configured to connect the pads and the first electrodes before forming the pad layer.

In an exemplary embodiment, a refractive index of the buffer layer 19 may range from 2 to 3, and exemplarily, a refractive index of the buffer layer 72 may be about 2.54. A fabrication material of the buffer layer 72 may include gallium nitride (GaN). A thickness of the buffer layer 18 may be about 2 μm.

In an exemplary embodiment, the first semiconductor layer 12 may be an N-type doped gallium nitride, the second electrodes may be N electrodes, the second semiconductor layer 14 may be a P-type doped gallium nitride, the first electrodes may be P electrodes, or the first semiconductor layer 12 may be a P-type doped gallium nitride, the second electrode may be a P-electrode, the second semiconductor layer 14 may be an N-type doped gallium nitride, and the first electrodes may be N electrodes. A thickness of the first semiconductor layer 12 may be about 2 μm. A thickness of the first semiconductor layer 14 may be about 2 μm.

In an exemplary embodiment, a thickness of the multiple quantum well layer 13 may be about 0.3 μm.

In an exemplary embodiment, a thickness of the first semiconductor layer 12, a thickness of the multiple quantum well layer 13 and a thickness of the second semiconductor layer 14 may all be set according to actual processes requirements.

In an exemplary embodiment, the first insulation layer 16 may be made of any one or more of silicon oxide (SiOx), silicon nitride (SiNx) and silicon oxynitride (SiON), and may be a single-layer, multi-layers or a composite layer.

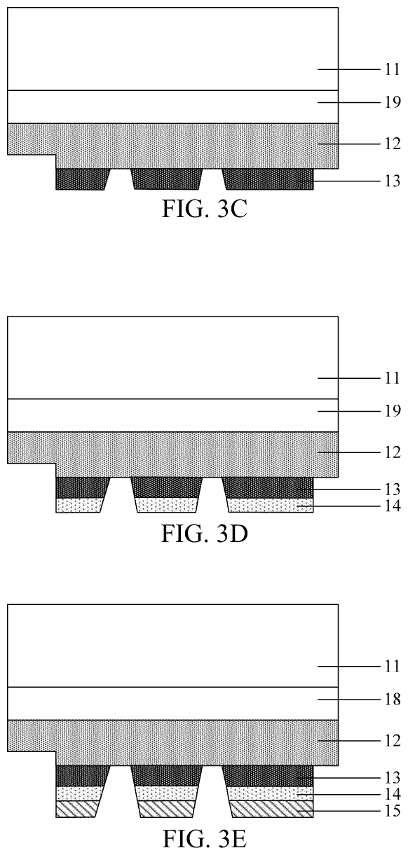

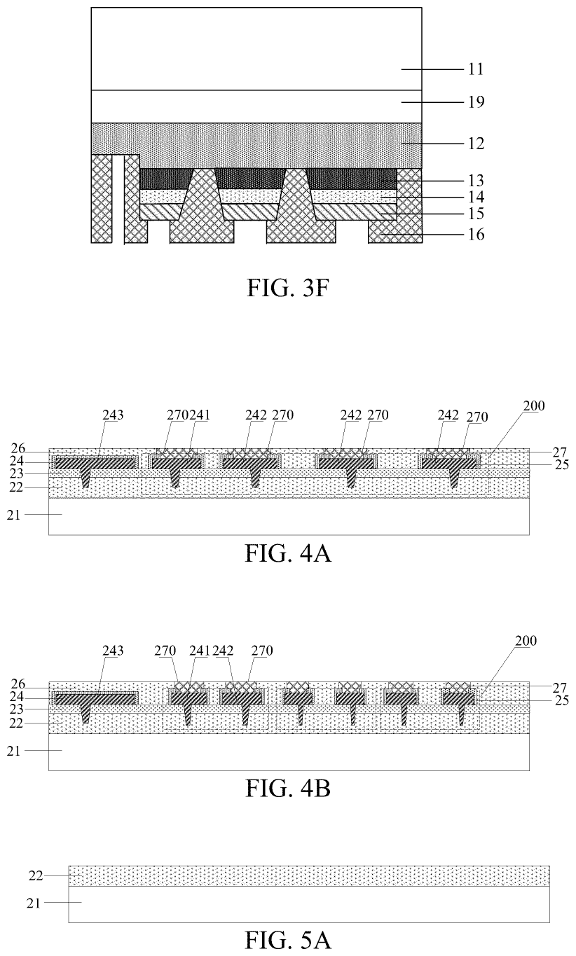

Taking a formation of the first backplane shown in FIG. 2A as an example, a technical solution of an embodiment of the present disclosure will be described with reference to FIG. 3A to FIG. 3F. It may be understood that for “patterning process” mentioned in the present disclosure, when a patterned material is an inorganic material or metal, the “patterning” includes a process such as photoresist coating, mask exposure, development, etching, and photoresist stripping, when the patterned material is an organic material, the “patterning” includes a process such as mask exposure and development, and evaporation, deposition, coating, and coating, etc., mentioned in the present disclosure are all mature preparation processes in the related art.

In step S11, a first substrate 11 is provided, a buffer thin film is deposited on a side of the first substrate 11, and a buffer layer 19 is generated on the first substrate through a patterning process, as shown in FIG. 3A, FIG. 3A is a schematic view after the buffer layer is formed.

In step S12, a first semiconductor thin film is deposited on the buffer layer 19, and the buffer thin film is processed through a patterning process to form a first semiconductor layer 12, as shown in FIG. 3B, FIG. 3B is a schematic view after the first semiconductor layer is formed.

In an exemplary embodiment, a surface of the first semiconductor layer away from the first substrate is uneven.

In step S13, a multiple quantum well thin film is deposited on the first semiconductor layer 12, and the multiple quantum well thin film is processed through a patterning process to form a multiple quantum well layer 13, as shown in FIG. 3C, FIG. 3C is a schematic view after the multiple quantum well layer is formed.

In step S14, a second semiconductor thin film is deposited on the multiple quantum well layer 13, and the second semiconductor thin film is processed through a patterning process to form a second semiconductor layer 14, as shown in FIG. 3D, FIG. 3D is a schematic view after the second semiconductor layer is formed.

In Step S15, a transparent conductive thin film is deposited on the second semiconductor layer 14, and the transparent conductive thin film is processed through a patterning process to form a transparent conductive layer 15, as shown in FIG. 3E, FIG. 3E is a schematic view after the transparent conductive layer is formed.

In step S16, a first insulation thin film is deposited on the transparent conductive layer 15, and first insulation thin film is processed through a patterning process to form a first insulation layer 16, as shown in FIG. 3F, FIG. 3F is a schematic view after the insulation layer is formed.

In Step S17, a conductive layer is deposited on the first insulation layer 16, and the conductive layer is processed through a patterning process to form a pad layer 17, as shown in FIG. 2A.

In one exemplary embodiment, FIG. 4A is a schematic view of a second backplane according to an exemplary embodiment, and FIG. 4B is a schematic view of a second backplane according to another exemplary embodiment. As shown in FIG. 4A and FIG. 4B, the second backplane includes a drive structure layer 22, a first planarization layer 23, a metal conductive layer 24, a second insulation layer 25, a second planarization layer 26, and a solder paste layer 27 arranged on the second substrate 21.

In an exemplary embodiment, Step S2 may include sequentially forming a drive structure layer, a first planarization layer, a metal conductive layer, a second insulation layer, a second planarization layer, and a solder paste layer on a second substrate. The metal conductive layer includes a connection electrode 200 and a power supply line 243, and the solder paste layer includes solder paste structures 700 arranged in an array. When the light emitting chips are different, structures of the connection electrodes connected to the light emitting chips are different.

In an exemplary embodiment, a power supply line 243 is configured to continuously provide a high-level signal.

When N=1, that is, when the light emitting chip includes one sub-pixel, each connection electrode 200 includes a first sub-connection electrode 241 and a second sub-connection electrode 242. The first sub-connection electrode is electrically connected to a first electrode in a corresponding light emitting chip, and the second sub-connection electrode is electrically connected to a second electrode in a corresponding light emitting chip. FIG. 2B is illustrated by taking N=1 as an example.

When N is not equal to 1, that is, when the light emitting chip includes at least two sub-pixels, each connection electrode includes N first sub-connection electrodes 241 and one second sub-connection electrode 242. The N first sub-connection electrodes are respectively electrically connected with first electrodes of N sub-pixels in a corresponding light emitting chip, and the second sub-connection electrode is electrically connected with second electrodes of N sub-pixels in a corresponding light emitting chip, and FIG. 2A is illustrated by taking that N is not equal to 1 as an example.

In an exemplary embodiment, each sub-connection electrode is connected to one solder paste structure, and different sub-connection electrodes are connected to different solder paste structures.

In an exemplary embodiment, the drive structure layer includes a plurality of thin film transistors. Each thin film transistor includes an active layer, a gate electrode, a source electrode, and a drain electrode. The thin film transistor may be of a top gate structure or a bottom gate structure, which is not limited in the present disclosure.

In an exemplary embodiment, a fabrication material of the first planarization layer and the second planarization layer may be made of an organic material.

In an exemplary embodiment, the metal conductive layer may be made of a metal material, such as any one or more of silver (Ag), copper (Cu), aluminum (Al) and molybdenum (Mo), or an alloy material of the above metals, such as AlNd alloy or MoNb alloy, which may have a single-layer structure or a multi-layer composite structure, such as Mo/Cu/Mo.

In an exemplary embodiment, the second insulation layer may be made of any one or more of silicon oxide (SiOx), silicon nitride (SiNx) and silicon oxynitride (SiON), and may be a single-layer, multi-layers or a composite layer.

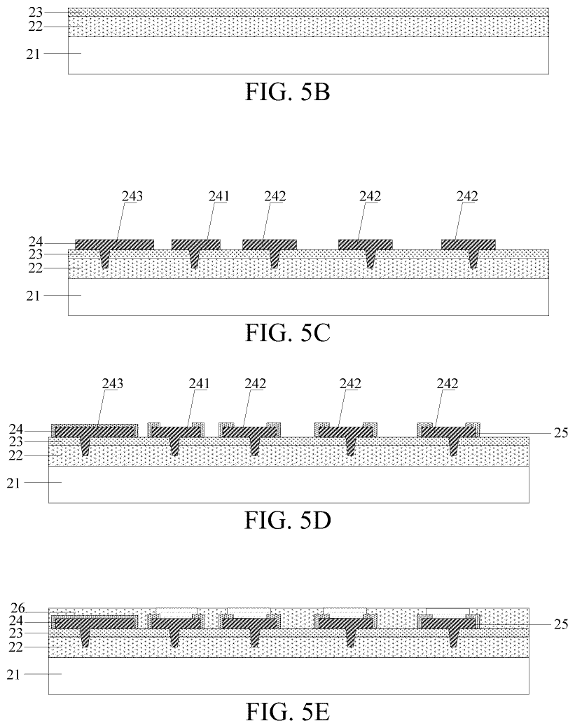

Taking formation of the second backplane shown in FIG. 4A as an example, a technical solution of an embodiment of the present disclosure will be described with reference to FIG. 5A to FIG. 5E.

In step S21, a second substrate 21 is provided, and a drive structure layer 22 is formed on a side of the second substrate 21, as shown in FIG. 5A, FIG. 5A is a schematic view after the drive structure layer is formed.

In an exemplary embodiment, forming the drive structure layer may include sequentially forming an active layer, a gate insulation layer, a gate electrode, an interlayer insulation layer, a source-drain electrode, and a passivation layer, or sequentially forming a gate electrode, a gate insulation layer, an active layer, a source-drain electrode, and a passivation layer.

In step S22, a first planarization thin film is coated on the drive structure layer 22, and the first planarization thin film is processed through a patterning process to form a first planarization layer 23, as shown in FIG. 5B, FIG. 5B is a schematic view after the first planarization layer is formed.

In step S23, a metal conductive thin film is deposited on the first planarization layer 23, and the metal conductive thin film is processed through a patterning process to form a metal conductive layer 24, as shown in FIG. 5C, FIG. 5C is a schematic view after the metal conductive layer is formed.

In step S24, a second insulation thin film is deposited on the metal conductive layer 24, and the second insulation thin film is processed through a patterning process to form a second insulation layer 25, as shown in FIG. 5D, FIG. 5D is a schematic view after the second insulation layer is formed.

In an exemplary embodiment, the second insulation layer is provided with a via hole that exposes a connection portion in the metal conductive layer.

In step S25, a second planarization thin film is coated on the second insulation layer 25, and the second planarization thin film is processed through a patterning process to form a second planarization layer 26, as shown in FIG. 5E, FIG. 5E is a schematic view after the second planarization layer is formed.

In an exemplary embodiment, the second planarization layer 26 may be provided with a via hole exposing a via hole of the insulation layer 25.

In step S26, a solder paste layer 27 is formed on the second planarization layer 26 through a spot welding process, as shown in FIG. 4A.

In an exemplary embodiment, step S3 may include transferring the first backplane to the second backplane to make the light emitting chips be electrically connected with corresponding connection electrodes, and peeling off the first substrate through a laser peeling process.

In another exemplary embodiment, step S3 may include transferring the first backplane to the third backplane to make the third backplane be bonded to the light emitting chip layer, peeling off the first substrate through a laser peeling process, peeling off the third backplane, and transferring the light emitting chip layer bonded with the third backplane to the second backplane.

In both of the above two embodiments, the first substrate on the first backplate may be peeled off, wherein in the first embodiment, the first substrate is peeled off after the first backplate is transferred to the second backplate, and in the second embodiment, the first substrate is peeled off before the first backplate is transferred to the second backplate.

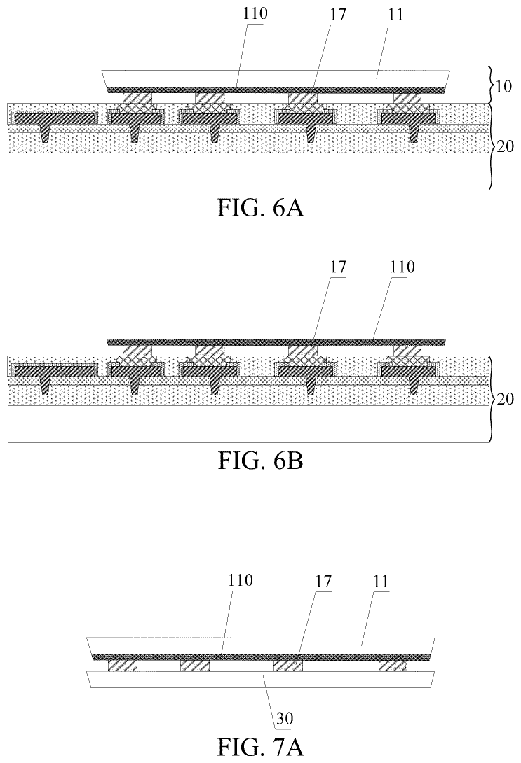

Step S3 according to an exemplary embodiment is illustrated below with reference to FIG. 6A to FIG. 6B.

In step S310, the first backplane 10 is transferred to the second backplane 20 to make the light emitting chips be electrically connected with corresponding connection electrodes, as shown in FIG. 6A.

In step S311, the first substrate is peeled off through a laser peeling process, as shown in FIG. 6B.

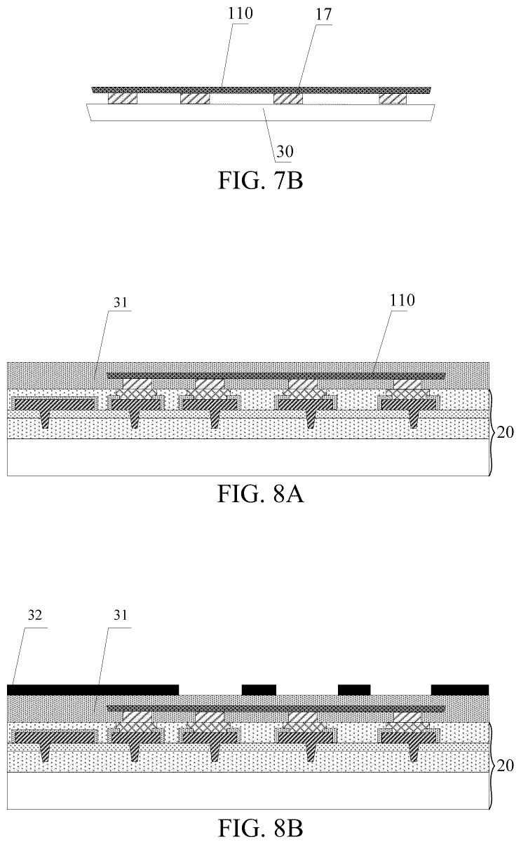

Step S3 according to another exemplary embodiment is illustrated below with reference to FIG. 7A to FIG. 7B.

In step S320, the first backplane 10 is transferred to the third backplane 30, as shown in FIG. 7A.

In step S321, the first substrate is peeled off through a laser peeling process, as shown in FIG. 7B.

In step S322, the third backplane is peeled off, and the light emitting chip layer bonded with the third backplane is transferred to the second backplane, as shown in FIG. 6B.

The first backplane in FIG. 6 and FIG. 7 is a simplified first backplane, a structure of the first backplane is actually the structure of FIG. 2A, and the first backplane may also be the structure of FIG. 2B or FIG. 2C. Herein, the intermediate film layer 110 includes a buffer layer, a first semiconductor layer, a multiple quantum well layer, a second semiconductor layer, a transparent conductive layer, and an insulation layer which are arranged sequentially from top to bottom.

In an exemplary embodiment, the step S4 may include the following steps.

In step S41, a colloid layer is formed through a coating or glue dispensing process on a side of the light emitting chip layer away from the second backplane.

In an exemplary embodiment, a thickness of the colloid layer may be about 10 μm, and the colloid layer may serve to protect and fix the light emitting chip layer. Fabrication material of the colloid layer may be silicone potting adhesive or epoxy resin.

In step S42, a black matrix layer is formed on the colloid layer.

In an exemplary embodiment, the black matrix layer is provided with a first via hole exposing each of the sub-pixels in the light emitting chip.

In step S43, a retaining wall and an optical film layer are sequentially formed on the black matrix layer.

In an exemplary embodiment, the optical film layer includes a first optical sub-film layer, a second optical sub-film layer and a third optical sub-film layer. The first optical sub-film layer is configured to convert the light of the first color into the light of the second color, the second optical sub-film layer is configured to convert the light of the first color into the light of the third color, and the third optical sub-film layer is configured to scatter the light of the first color.

In an exemplary embodiment, the first optical sub-film layer may include a second color quantum dot material. The second optical sub-film layer may include a third color quantum dot material.

In an exemplary embodiment, the third optical sub-film layer may include scattering particles, which may be material particles with a high refractive index, and the refractive index of the scattering particles may be greater than or equal to 1.7, and a material of the scattering particles may be a silane-containing resin material.

In an exemplary embodiment, the light of the second color is generated by the first optical sub-film layer under the excitation of the light emitting chip, and the light of the third color is generated by the second optical sub-film layer under the excitation of the light emitting chip, so the generated light type of the second color is consistent with that of the third color, and the first color is directly generated by the light emitting chip. As a result, a light type of the first color is inconsistent with those of the second color and the third color. By arranging the third optical sub-film layer, the light type of the first color displayed may be improved, a light intensity consistency of the first color, the second color and the third color at a same angle may be improved, and the display effect may be improved.

In an exemplary embodiment, thicknesses of the first optical sub-film layer, the second optical sub-film layer, and the third optical sub-film layer may be the same. In this way, an optical path consistency of the first color, the second color and the third color may be improved, and the display effect can be improved.

In an exemplary embodiment, when N=1, each sub-pixel includes one of the first optical sub-film layer, the second optical sub-film layer, and the third optical sub-film layer, and sub-pixels of adjacent light emitting chips include different optical sub-film layers.

In an exemplary embodiment, when N=3, three sub-pixels located in the same light emitting chip respectively include the first optical sub-film layer, the second optical sub-film layer and the third optical sub-film layer, three sub-pixels located in different light emitting chips include a same optical sub-film layer, or three sub-pixels located in the same light emitting chip include a same optical sub-film layer, and three sub-pixels located in different light emitting chips include different optical sub-film layers.

In an exemplary embodiment, when N is a positive integer that is not equal to 1 and not equal to 3, three sub-pixels located in the same light emitting chip include a same optical sub-film layer, and three sub-pixels located in different light emitting chips include different optical sub-film layers.

In an exemplary embodiment, an orthographic projection of the optical sub-film layer in each sub-pixel on the second backplane is overlapped at least partially with an orthographic projection of the multiple quantum well layer in the sub-pixel on the second backplane.

In an exemplary embodiment, a distance between optical sub-film layers of adjacent sub-pixels is about 20 microns.

In an exemplary embodiment, step S43 may include forming a retaining wall on the black matrix layer, and the retaining wall is provided with a second via hole exposing the first via hole; depositing a first optical thin film, a second optical thin film and a third optical thin film on the retaining wall, performing processing on the first optical thin film through a patterning process to form a first optical sub-film layer, performing processing on the second optical thin film through a patterning process to form a second optical sub-film layer, and performing processing on the third optical thin film through a patterning process to form a third optical sub-film layer.

In another exemplary embodiment, step S43 may include forming a retaining wall on the black matrix layer, wherein an orthographic projection of the retaining wall on the second backplane covers an orthographic projection of the first via hole on the second backplane; injecting first optical particles, second optical particles and third optical particles into the retaining wall to form a first optical sub-film layer, a second optical sub-film layer and a third optical sub-film layer.

In an exemplary embodiment, the first optical particles may be second color quantum dot particles, the second optical particles may be third color quantum dot particles, and the third optical particles may be scattering particles.

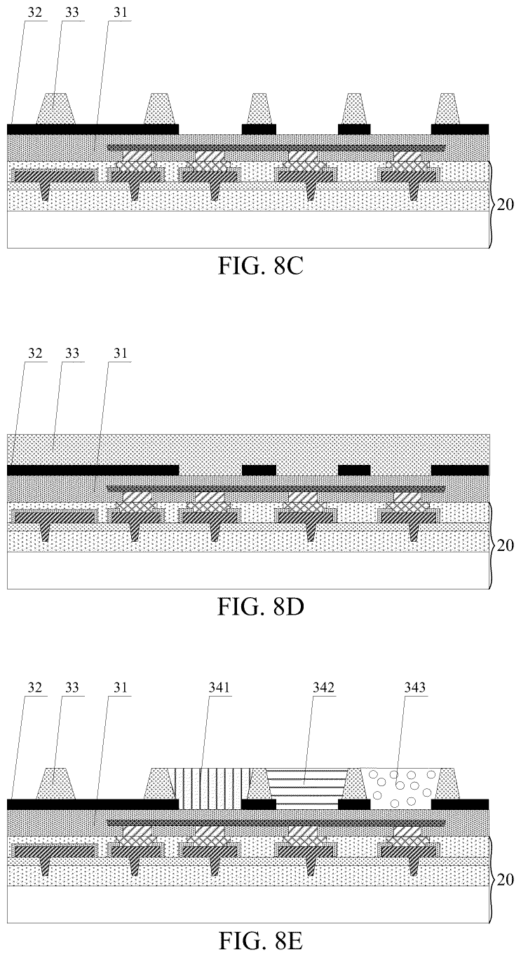

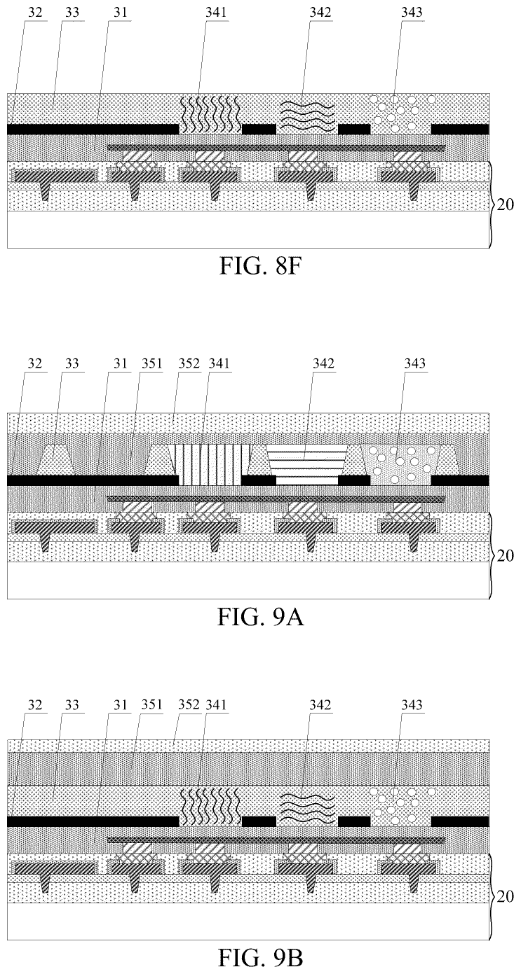

A technical solution of step S4 according to an exemplary embodiment is illustrated below with reference to FIG. 8A to FIG. 8F. In step S410, a colloid layer 31 is formed on a side of the light emitting chip layer away from the second backplane through a coating or glue dispensing process, as shown in FIG. 8A, FIG. 8A is a schematic view of forming the colloid layer.

In step S411, a black matrix thin film is coated on the colloid layer 31, and the black matrix thin film is processed through a patterning process to form a black matrix layer 32, as shown in FIG. 8B, FIG. 8B is a schematic view after the black matrix layer is formed.

In an exemplary embodiment, the black matrix layer is provided with a first via hole exposing each sub-pixel in the light emitting chip.

In step S412, a retaining wall thin film is deposited on the black matrix layer, and the retaining wall thin film is patterned through a patterning process to form the retaining wall 33, as shown in FIG. 8C and FIG. 8D, wherein FIG. 8C is a first schematic view after the retaining wall is formed, and FIG. 8D is a second schematic view after the retaining wall is formed.

In an exemplary embodiment, the retaining wall 33 may be provided with a second via hole exposing the first via hole, or an orthographic projection of the retaining wall 33 on the second backplane covers an orthographic projection of the first via hole on the second backplane. FIG. 8C is illustrated by taking that the retaining wall 33 being provided with a second via hole exposing the first via hole as an example, and FIG. 8D is illustrated by taking that an orthographic projection of the retaining wall 33 on the second backplane covers an orthographic projection of the first via hole on the second backplane as an example.

When the retaining wall 33 is provided with a second via hole exposing the first via hole, in step S413, a first optical thin film, a second optical thin film and a third optical thin film are deposited on the retaining wall, wherein the first optical thin film is processed through a patterning process to form a first optical sub-film layer, the second optical thin film is processed through a patterning process to form a second optical sub-film layer, and the third optical thin film is processed through a patterning process to form a third optical sub-film layer, as shown in FIG. 8E, FIG. 8E is a first schematic view after the optical film layer is formed.

When the orthographic projection of the retaining wall 33 on the second backplane covers the orthographic projection of the first via hole on the second backplane, in step S413, first optical particles, second optical particles, and third optical particles are injected into the retaining wall 33 to form the first optical sub-film layer 341, the second optical sub-film layer 342, and the third optical sub-film layer 343, as shown in FIG. 8F, FIG. 8F is a second schematic view after the optical film layer is formed.

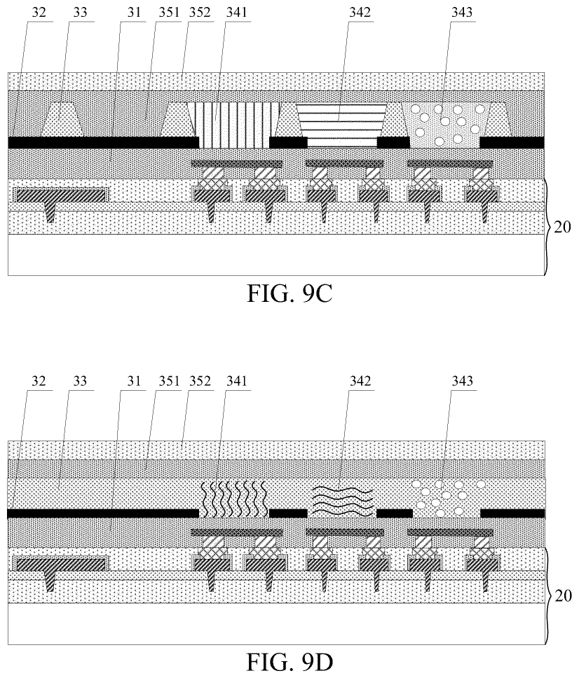

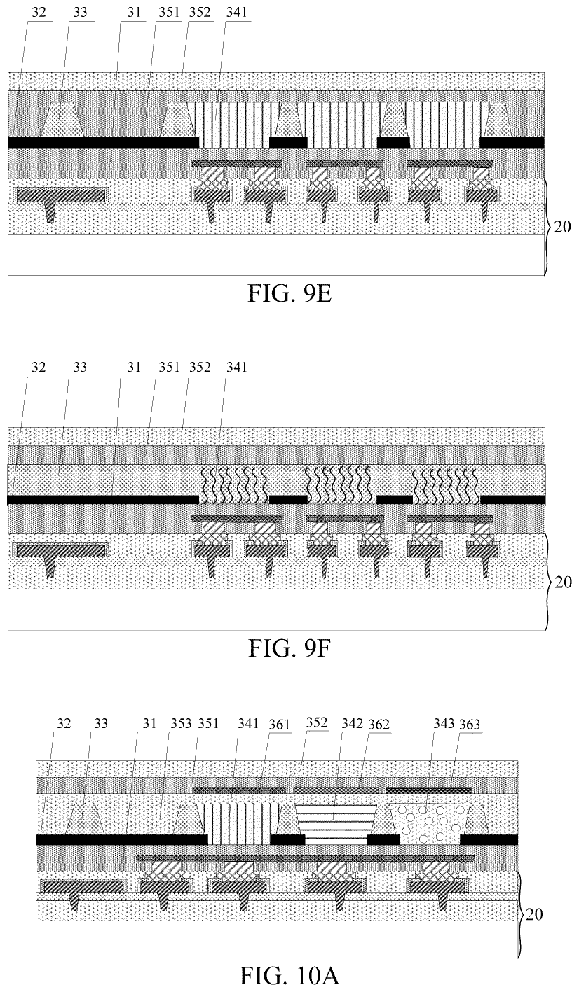

In an exemplary embodiment, FIG. 9 is a first schematic view after an encapsulation layer is formed, and after step S4, the method for preparing the display substrate may further include sequentially forming an organic encapsulation layer 351 and a first inorganic encapsulation layer 352 on the optical film layer.

In an exemplary embodiment, FIG. 9A is a first schematic view after a first inorganic encapsulation layer is formed according to an exemplary embodiment, FIG. 9B is a second schematic view after a first inorganic encapsulation layer is formed according to an exemplary embodiment, FIG. 9C is a third schematic view after a first inorganic encapsulation layer is formed according to an exemplary embodiment, FIG. 9D is a fourth schematic view after a first inorganic encapsulation layer is formed according to an exemplary embodiment, FIG. 9E is a fifth schematic view after a first inorganic encapsulation layer is formed according to an exemplary embodiment, and FIG. 9F is a sixth schematic view after a first inorganic encapsulation layer is formed according to an exemplary embodiment. As shown in FIG. 9A to FIG. 9F, after step S4, the method for preparing the display substrate may further include sequentially forming an organic encapsulation layer 351 and a first inorganic encapsulation layer 352 on the optical film layer. FIG. 9A is illustrated by taking that the first backplane is the first backplane of FIG. 2A, the second backplane is the second backplane of FIG. 4A, and the retaining wall 33 is provide with a second via hole exposing the first via hole as an example. FIG. 9B is illustrated by taking that the first backplane is the first backplane of FIG. 2A, the second backplane is the second backplane of FIG. 4A, and an orthographic projection of the retaining wall 33 on the second backplane covers an orthographic projection of the first via hole on the second backplane as an example. FIG. 9C is illustrated by taking that the first backplane is the first backplane of FIG. 2C, the second backplane is the second backplane of FIG. 4B, and the retaining wall is provide with a second via hole exposing the first via hole as an example. FIG. 9D is illustrated by taking that the first backplane is the first backplane of FIG. 2C, the second backplane is the second backplane of FIG. 4B, and an orthographic projection of the retaining wall on the second backplane covers an orthographic projection of the first via hole on the second backplane as an example. FIG. 9E is illustrated by taking that the first backplane is the first backplane of FIG. 2B, the second backplane is the second backplane of FIG. 4A, and the retaining wall 33 is provide with a second via hole exposing the first via hole as an example. FIG. 9F is illustrated by taking that the first backplane is the first backplane of FIG. 2B, the second backplane is the second backplane of FIG. 4A, and an orthographic projection of the retaining wall on the second backplane covers an orthographic projection of the first via hole on the second backplane as an example.

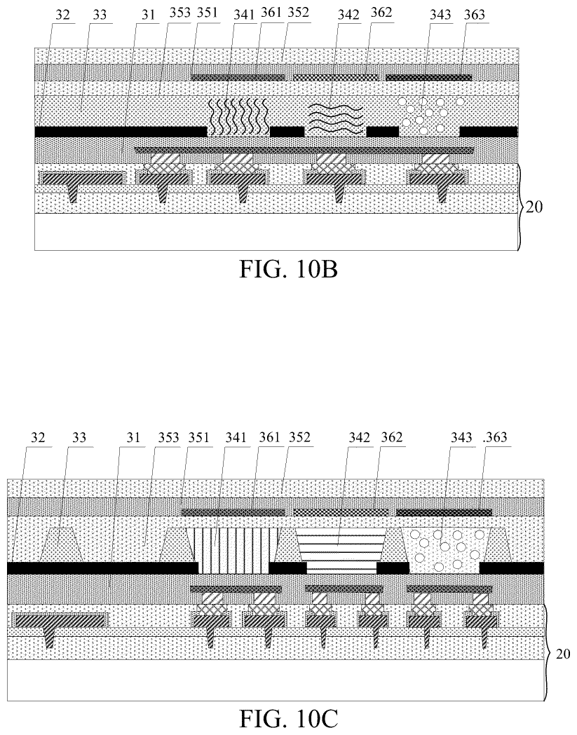

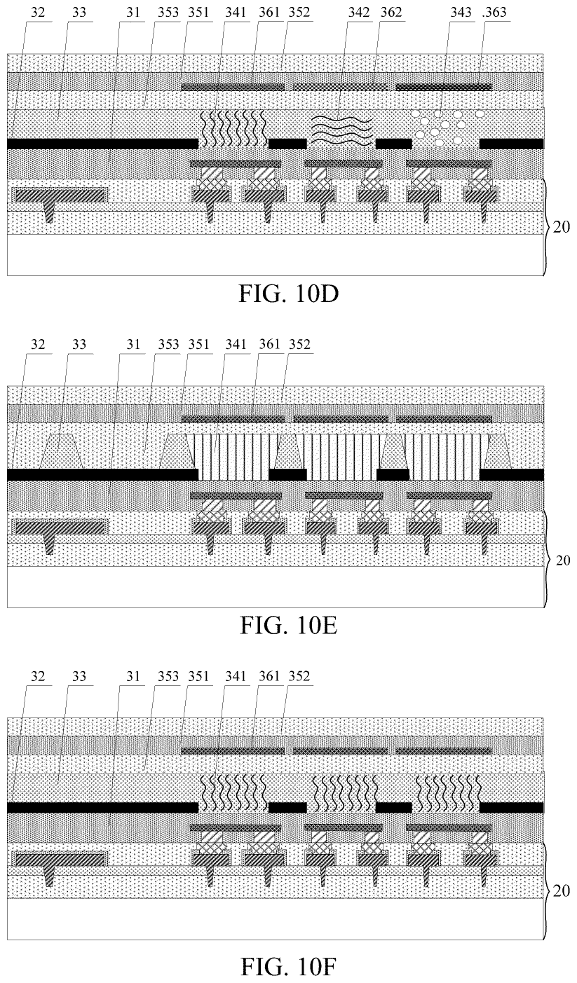

In an exemplary embodiment, FIG. 10A is a first schematic view after a first inorganic encapsulation layer is formed according to another exemplary embodiment, FIG. 10B is a second schematic view after a first inorganic encapsulation layer is formed according to another exemplary embodiment, FIG. 10C is a third schematic view after a first inorganic encapsulation layer is formed according to another exemplary embodiment, FIG. 10D is a fourth schematic view after a first inorganic encapsulation layer is formed according to another exemplary embodiment, FIG. 10E is a fifth schematic view after a first inorganic encapsulation layer is formed according to another exemplary embodiment, and FIG. 10F is a sixth schematic view after a first inorganic encapsulation layer is formed according to another exemplary embodiment. As shown in FIG. 10A to FIG. 10F, after step S4, the method for preparing the display substrate may further include forming a second inorganic encapsulation layer 353 on the optical film layer, forming a color film layer on the second inorganic encapsulation layer 353, and sequentially forming an organic encapsulation layer 351 and a first inorganic encapsulation layer 352 on the color film layer.

In an exemplary embodiment, as shown in FIG. 10A to FIG. 10F, the color film layer may include a first color film layer 361, a second color film layer 362 and a third color film layer 363.

In an exemplary embodiment, the first color film layer 361 is in one-to-one correspondence with the first optical sub-film layer 341, and an orthographic projection of the first color film layer 361 on the second backplane 20 covers an orthographic projection of the corresponding first optical sub-film layer 341 on the second backplane 20.

In an exemplary embodiment, the second color film layer 362 is in one-to-one correspondence with the second optical sub-film layer 342, and an orthographic projection of the second color film layer 362 on the second backplane 20 covers an orthographic projection of the corresponding second optical sub-film layer 342 on the second backplane 20.

In an exemplary embodiment, the third color film layer 363 is in one-to-one correspondence with the third optical sub-film layer 343, and an orthographic projection of the third color film layer 363 on the second backplane 20 covers an orthographic projection of the corresponding third optical sub-film layer 343 on the second backplane 20.

FIG. 10A is illustrated by taking that the first backplane is the first backplane of FIG. 2A, the second backplane is the second backplane of FIG. 4A, and the retaining wall 33 is provide with a second via hole exposing the first via hole as an example. FIG. 10B is illustrated by taking that the first backplane is the first backplane of FIG. 2A, the second backplane is the second backplane of FIG. 4A, and an orthographic projection of the retaining wall 33 on the second backplane covers an orthographic projection of the first via hole on the second backplane as an example. FIG. 10C is illustrated by taking that the first backplane is the first backplane of FIG. 2C, the second backplane is the second backplane of FIG. 4B, and the retaining wall is provide with a second via hole exposing the first via hole as an example. FIG. 10D is illustrated by taking that the first backplane is the first backplane of FIG. 2C, the second backplane is the second backplane of FIG. 4B, and an orthographic projection of the retaining wall on the second backplane covers an orthographic projection of the first via hole on the second backplane as an example. FIG. 10E is illustrated by taking that the first backplane is the first backplane of FIG. 2B, the second backplane is the second backplane of FIG. 4A, and the retaining wall 33 provide with a second via hole exposing the first via hole as an example. FIG. 10F is illustrated by taking that the first backplane is the first backplane of FIG. 2B, the second backplane is the second backplane of FIG. 4A, and an orthographic projection of the retaining wall on the second backplane covers an orthographic projection of the first via hole on the second backplane as an example.

An embodiment of the present disclosure further provides a display substrate, which is prepared by using a method for preparing a display substrate.

The method for preparing the display substrate is the method according to any of the above embodiments, and has similar implementation principles and implementation effects, which will not be repeated here.

An embodiment of the present disclosure further provides a display apparatus, which includes the display substrate according to any one of the embodiments.

The display substrate includes the display substrate according to any one of the embodiments, and has similar implementation principles and implementation effects, which will not be repeated here.

In an exemplary embodiment, the display apparatus may be any product or component having a display function such as a mobile phone, a tablet computer, a television, a display, a laptop computer, a digital photo frame, or a navigator.

The accompanying drawings of the present disclosure only involve the structures involved in the embodiments of the present disclosure, and the other structures may refer to conventional designs.

For the sake of clarity, a thickness and size of a layer or a micro structure are enlarged in the accompanying drawings used for describing the embodiments of the present disclosure. It may be understood that when an element such as a layer, film, region, or substrate is described as being “on” or “under” another element, the element may be “directly” located “on” or “under” the another element, or there may be an intermediate element.

Although the implementations of the present disclosure are disclosed above, the contents are only implementations for ease of understanding of the present disclosure and not intended to limit the present disclosure. Any of those skilled in the art of the present disclosure can make any modifications and variations in the implementation and details without departing from the spirit and scope of the present disclosure. However, the protection scope of the present disclosure should be subject to the scope defined by the appended claims.

1. A method for preparing a display substrate, comprising:
providing a first substrate, and forming a light emitting chip layer on the first substrate to form a first backplane, wherein the light emitting chip layer comprises light emitting chips arranged in an array, which are configured to emit light of a first color and comprise N sub-pixels, and N is a positive integer greater than or equal to 1;
providing a second substrate, and forming a drive circuit layer on the second substrate to form a second backplane, wherein the drive circuit layer comprises connection electrodes arranged in an array, and the light emitting chips are in one-to-one correspondence with the connection electrodes;
transferring the first backplane from which the first substrate is peeled off to the second backplane to make the light emitting chips be electrically connected with corresponding connection electrodes; and
forming an optical film layer on a side of the light emitting chip layer away from the second backplane, wherein the optical film layer is configured to scatter the light of the first color, convert the light of the first color into light of a second color, and convert the light of the first color into light of a third color.

2. The method according to claim 1, wherein each sub-pixel comprises: a first pixel semiconductor layer, a second pixel semiconductor layer, a pixel multiple quantum well layer, a first electrode and a second electrode;
forming the light emitting chip layer on the first substrate comprises:
sequentially growing a buffer layer, a first semiconductor layer, a multiple quantum well layer, a second semiconductor layer, a transparent conductive layer, a first insulation layer and a pad layer on a side of the first substrate, wherein the first semiconductor layer comprises a first pixel semiconductor layer, the multiple quantum well layer comprises a pixel multiple quantum well layer, the second semiconductor layer comprises a second pixel semiconductor layer, the transparent conductive layer comprises the first electrode, and the pad layer comprises the second electrode and a pad, and the pad is connected with the first electrode;
when N is greater than 1, first pixel semiconductor layers of different sub-pixels are a same film layer, pixel multiple quantum well layers, second pixel semiconductor layers and first electrodes of different sub-pixels are spaced apart from each other, second electrodes of different sub-pixels are a same electrode, and the first electrodes of different sub-pixels are connected with different pads; and
wherein an orthographic projection of the pad on the first substrate is at least partially overlapped with or not overlapped with an orthographic projection of the first electrode to which the pad is connected on the first substrate.

3. The method according to claim 2, wherein forming the drive circuit layer on the second substrate comprises:
sequentially forming a drive structure layer, a first planarization layer, a metal conductive layer, a second insulation layer, a second planarization layer and a solder paste layer on the second substrate, wherein the metal conductive layer comprises a connection electrode, and the solder paste layer comprises solder paste structures arranged in an array;
when N=1, each connection electrode comprises a first sub-connection electrode and a second sub-connection electrode, wherein the first sub-connection electrode is electrically connected to a first electrode in a corresponding light emitting chip, and the second sub-connection electrode is electrically connected to a second electrode in a corresponding light emitting chip;
when N is not equal to 1, each connection electrode comprises N first sub-connection electrodes and one second sub-connection electrode, wherein the N first sub-connection electrodes are respectively electrically connected with first electrodes of N sub-pixels in a corresponding light emitting chip, and the second sub-connection electrode is electrically connected with second electrodes of N sub-pixels in the corresponding light emitting chip; and
each of the sub-connection electrodes is connected to one solder paste structure, and different sub-connection electrodes are connected to different solder paste structures.

4. The method according to claim 1, wherein transferring the first backplane from which the first substrate is peeled off to the second backplane comprises:
transferring the first backplane to the second backplane to make the light emitting chips be electrically connected with the corresponding connection electrodes; and
peeling off the first substrate through a laser peeling process.

5. The method according to claim 1, wherein transferring the first backplane from which the first substrate is peeled off to the second backplane comprises:
transferring the first backplane to a third backplane to make the third backplane be bonded with the light emitting chip layer;
peeling off the first substrate through a laser peeling process; and
peeling off the third backplane, and transferring the light emitting chip layer bonded with the third backplane to the second backplane.

6. The method according to claim 1, wherein forming the optical film layer on the side of the light emitting chip layer away from the second backplane comprises:
forming a colloid layer through a coating or glue dispensing process on the side of the light emitting chip layer away from the second backplane;
forming a black matrix layer on the colloid layer, wherein the black matrix layer is provided with a first via hole exposing each sub-pixel in the light emitting chip;
sequentially forming a retaining wall and an optical film layer on the black matrix layer, wherein the optical film layer comprises a first optical sub-film layer, a second optical sub-film layer and a third optical sub-film layer; the first optical sub-film layer is configured to convert the light of the first color into the light of the second color, the second optical sub-film layer is configured to convert the light of the first color into the light of the third color, and the third optical sub-film layer is configured to scatter the light of the first color;
when N=1, each sub-pixel comprises one of the first optical sub-film layer, the second optical sub-film layer, and the third optical sub-film layer; sub-pixels of adjacent light emitting chips comprise different optical sub-film layers;
when N=3, three sub-pixels located in a same light emitting chip respectively comprise the first optical sub-film layer, the second optical sub-film layer and the third optical sub-film layer, three sub-pixels located in different light emitting chips comprise a same optical sub-film layer, or the three sub-pixels located in the same light emitting chip comprise a same optical sub-film layer, and the three sub-pixels located in different light emitting chips comprise different optical sub-film layers;
when N is a positive integer that is not equal to 1 and not equal to 3, the three sub-pixels located in the same light emitting chip comprise a same optical sub-film layer, and the three sub-pixels located in different light emitting chips comprise different optical sub-film layers; and
an orthographic projection of the optical sub-film layer in each sub-pixel on the second backplane is overlapped at least partially with an orthographic projection of the multiple quantum well layer in each sub-pixel on the second backplane.

7. The method according to claim 6, wherein sequentially forming the retaining wall and the optical film layer on the black matrix layer comprises:
forming the retaining wall on the black matrix layer, wherein the retaining wall is provided with a second via hole exposing the first via hole; and
depositing a first optical thin film, a second optical thin film and a third optical thin film on the retaining wall, processing the first optical thin film through a patterning process to form the first optical sub-film layer, processing the second optical thin film through a patterning process to form the second optical sub-film layer, and processing the third optical thin film through a patterning process to form the third optical sub-film layer.

8. The method according to claim 6, wherein sequentially forming the retaining wall and the optical film layer on the black matrix layer comprises:
forming the retaining wall on the black matrix layer, wherein an orthographic projection of the retaining wall on the second backplane covers an orthographic projection of the first via hole on the second backplane; and
injecting first optical particles, second optical particles and third optical particles into the retaining wall to form the first optical sub-film layer, the second optical sub-film layer and the third optical sub-film layer.

9. The method according to claim 1, wherein after forming the optical film layer on the side of the light emitting chip layer away from the second backplane, the method further comprises:
sequentially forming an organic encapsulation layer and a first inorganic encapsulation layer on the optical film layer.

10. The method according to claim 1, wherein after forming the optical film layer on a side of the light emitting chip layer away from the second backplane, the method further comprises:
forming a second inorganic encapsulation layer on the optical film layer;
forming a color film layer on the second inorganic encapsulation layer, wherein the color film layer comprises a first color film layer, a second color film layer and a third color film layer;
the first color film layer is in one-to-one correspondence with a first optical sub-film layer, an orthographic projection of the first color film layer on the second backplane covers an orthographic projection of the corresponding first optical sub-film layer on the second backplane, the second color film layer is in one-to-one correspondence with a second optical sub-film layer, an orthographic projection of the second color film layer on the second backplane covers an orthographic projection of the corresponding second optical sub-film layer on the second backplane, the third color film layer is in one-to-one correspondence with a third optical sub-film layer, and an orthographic projection of the third color film layer on the second backplane covers an orthographic projection of the corresponding third optical sub-film layer on the second backplane; and
sequentially forming an organic encapsulation layer and a first inorganic encapsulation layer on the color film layer.

11. The method according to claim 1, wherein the first substrate is a sapphire substrate.

12. A display substrate prepared by using the method for preparing the display substrate according to claim 1.

13. A display apparatus, comprising the display substrate according to claim 12.
